(19) United States
(12) Patent Application Publication
(10) Pub. No.: US 2024/0393364 A1
(43) Pub. Date: Nov. 28, 2024

(54) SYSTEMS AND METHODS FOR TEST SOCKETS HAVING SCRUBBING CONTACTS

(71) Applicant: Smiths Interconnect Americas, Inc., Kansas City, KS (US)

(72) Inventors: Jiachun Zhou, Fremont, CA (US); Justin Bahaj, Kansas, MO (US); Siang Soh, Milpitas, CA (US); Xiaofei Ji, Suzhou, Jiangsu (CN)

(21) Appl. No.: 18/696,008

(22) PCT Filed: Sep. 26, 2022
(86) PCT No.: PCT/US2022/044682

§ 371 Date: Mar. 27, 2024

(30) Foreign Application Priority Data
Sep. 27, 2021 (CN) 202111137600.9

(51) Int. Cl. G01R 1/04; G01R 31/28; H05K 7/10

(52) U.S. Cl. CPC G01R 1/0466; G01R 31/2889; H05K 7/1007

(57) ABSTRACT

A test socket for a semiconductor integrated circuit (IC) is provided. The test socket includes a socket body configured to engage the semiconductor IC and a load board and an elastomer retainer including a top surface adjacent to the socket body and configured to face the semiconductor IC, and a bottom surface configured to face a load board. The elastomer retainer defines a slot extending from the top surface to the bottom surface. The test socket further includes a rotational contact positioned in the slot. The rotational contact is configured to move between a free state, a pre-load state, and a loaded state. The elastomer retainer is configured to compress under a pre-load force from the rotational contact when moving from the free state to the pre-load state, and compress under a loading force from the rotational contact when moving from the pre-load state to the loaded state.

### BACKGROUND

The field of the disclosure relates generally to a test socket for semiconductor integrated circuits and, more specifically, a test socket with rotational contacts that translate, or “scrub,” on the contact pads of the integrated circuit under test.

Semiconductor integrated circuits (ICs) are produced in various packages, or chip configurations, including, for example, a quad flat no-leads (QFN) package that is common in many IC applications and is produced in large quantities. Production of ICs of any quantity generally includes testing of the ICs in a manner that simulates an end-user's application of those ICs. One manner of testing ICs is to connect each IC to a printed circuit board (PCB) that exercises the contacts and various functionalities of the IC. That PCB is sometimes referred to as a load board, and can be re-used to test many ICs. A fundamental component of the load board that enables such testing is a test socket for the IC that can be re-used many times to test large quantities of the IC. The test socket connects, both electrically and mechanically, the IC to the load board. The degree to which the test socket can be re-used is quantified by how many “cycles” it can withstand without degrading performance, e.g., signal performance. Each time an IC is inserted, or set, into the test socket is referred to as one cycle. Generally, over the course of many cycles, electrical and mechanical properties of the contacts and structures of the test socket begin to degrade as a result of, for example, oxidation, abrasion, compression, tension, or other forms of wear. Such degradation eventually impacts integrity of the testing itself, at which point the test socket reaches the end of its useful life. Accordingly, test sockets that maintain good electrical and mechanical performance for long life cycles are desired.

### BRIEF SUMMARY

In one aspect, a test socket for a semiconductor integrated circuit (IC) is provided. The test socket includes a socket body configured to engage the semiconductor IC and a load board. The test socket further includes an elastomer retainer including a top surface adjacent to the socket body and configured to face the semiconductor IC, and a bottom surface, opposite the top surface, configured to face a load board. The elastomer retainer defines a slot extending from the top surface to the bottom surface. The test socket further includes a rotational contact positioned in the slot. The rotational contact is configured to move between a free state and a pre-load state, and to move between the pre-load state and a loaded state. The elastomer retainer is configured to compress under a pre-load force from the rotational contact when moving from the free state to the pre-load state upon engagement of the socket body with the load board, and compress under a loading force from the rotational contact when moving from the pre-load state to the loaded state upon engagement of the socket body with the semiconductor IC.

In another aspect, a test system for a semiconductor integrated circuit (IC) is provided. The test system includes a load board and a test socket. The test socket includes a socket body configured to engage the semiconductor IC and a load board. The test socket further includes an elastomer retainer including a top surface adjacent to the socket body configured to face the semiconductor IC, and a bottom surface, opposite the top surface, configured to face the load board. The elastomer retainer defines a slot extending from the top surface to the bottom surface. The test socket further includes a rotational contact positioned in the slot/The rotational contact is configured to move between a free state and a pre-load state, and to move between the pre-load state and a loaded state. The elastomer retainer is configured to compress under a pre-load force from the rotational contact when moving from the free state to the pre-load state upon engagement of the socket body with the load board, and compress under a loading force from the rotational contact when moving from the pre-load state to the loaded state upon engagement of the socket body with the semiconductor IC.

In another aspect, a method for assembling a test system for a semiconductor integrated circuit (IC) is provided. The method includes positioning a socket body configured to engage the semiconductor IC and a load board adjacent to a top surface of an elastomer retainer. The top surface is configured to face the semiconductor IC. The elastomer retainer further includes a bottom surface, opposite the top surface, configured to face the load board. The elastomer retainer defines a slot extending from the top surface to the bottom surface. The method further includes positioning a rotational contact in the slot. The rotational contact is configured to move between a free state and a pre-load state, and to move between the pre-load state and a loaded state. The elastomer retainer is configured to compress under a pre-load force from the rotational contact when moving from the free state to the pre-load state upon engagement of the socket body with the load board, and compress under a loading force from the rotational contact when moving from the pre-load state to the loaded state upon engagement of the socket body with the semiconductor IC.

### BRIEF DESCRIPTION OF THE DRAWINGS

FIGS. 1-11 show example embodiments of the systems and methods described herein.

FIG. 1 is a cross-sectional diagram of an example IC test system;

FIG. 2 is a perspective diagram of an example test socket for a QFN IC for use with the IC test system shown in FIG. 1;

FIG. 3 is a cross-sectional diagram of the test socket shown in FIGS. 1 and 2 having a rotational contact in a free state;

FIG. 4 is a cross-sectional diagram of the test socket shown in FIGS. 1-3 having the rotational contact in a pre-load state;

FIG. 5 a cross-sectional diagram of the test socket shown in FIGS. 1-4 having the rotational contact in a loaded state;

FIG. 6 is a perspective diagram of the rotational contact shown in FIGS. 3-6;

FIG. 7 is a partially transparent perspective diagram of the test socket shown in FIGS. 1-5 having the rotational contact in the free state;

FIG. 8 is a perspective diagram of an elastomer retainer for use with the test socket shown in FIGS. 1-5 and 7, and the rotational contact shown in FIG. 6;

FIG. 9 is another perspective view of the elastomer retainer shown in FIG. 8;

FIG. 10 is an exploded view of the test socket shown in FIGS. 1-5 and 7; and

FIG. 11 is a flow diagram of a method of assembling a test system for a semiconductor IC.

### DETAILED DESCRIPTION

Embodiments of the test socket described herein provide a rotational contact that, when engaged with a load board and an IC under test, produces scrub on a contact pad of the IC. The described test sockets are configured to receive a flat no-leads IC package, such as a QFN IC, where scrub on the contact pad of the IC is desirable to reduce contact electrical resistance of the electrical connection between the IC and the rotational contact of the test socket. Conversely, the test sockets described herein generally minimize translation, or scrub, by the rotational contact on the PCB contact of the load board.

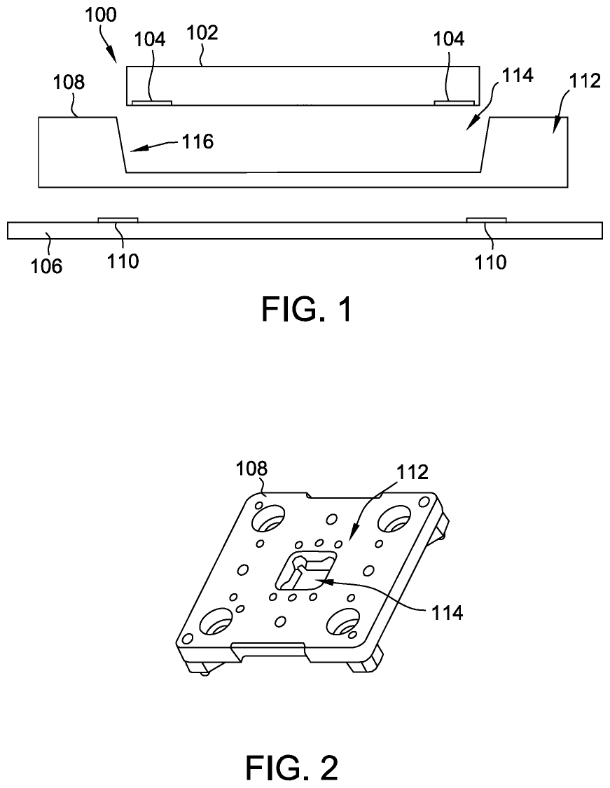

FIG. 1 is a cross-sectional diagram of an example IC test system 100 for testing a semiconductor IC 102. IC 102 is one or more electronic circuits packaged into a single semiconductor chip generally including a plurality of contact pads 104 for conducting signals to and from the circuits within the package. IC test system 100 includes a load board 106 onto which a test socket 108 is mounted. Load board 106 includes PCB contacts 110 that will connect IC 102 to a load circuit, or test circuit (not shown), integrated with load board 106. Test socket 108 is a re-usable interface for connecting many units of IC 102 to load board 106. FIG. 2 is a perspective diagram of test socket 108 for a QFN IC, such as IC 102. Test socket 108 includes a socket body 112 that defines a receptacle 114 that receives IC 102. In certain embodiments of test socket 108, socket body 112 includes guide walls 116 that may be straight or tapered for guiding IC 102 into receptacle 114 to ensure proper alignment of contact pads 104 with PCB contacts 110. More specifically, guide walls 116 align contact pads 104 with corresponding contacts (not shown) of test socket 108. The contacts of test socket 108 extend through socket body 112 to electrically connect each contact pad 104 of IC 102 with a corresponding PCB contact 110 on load board 106.

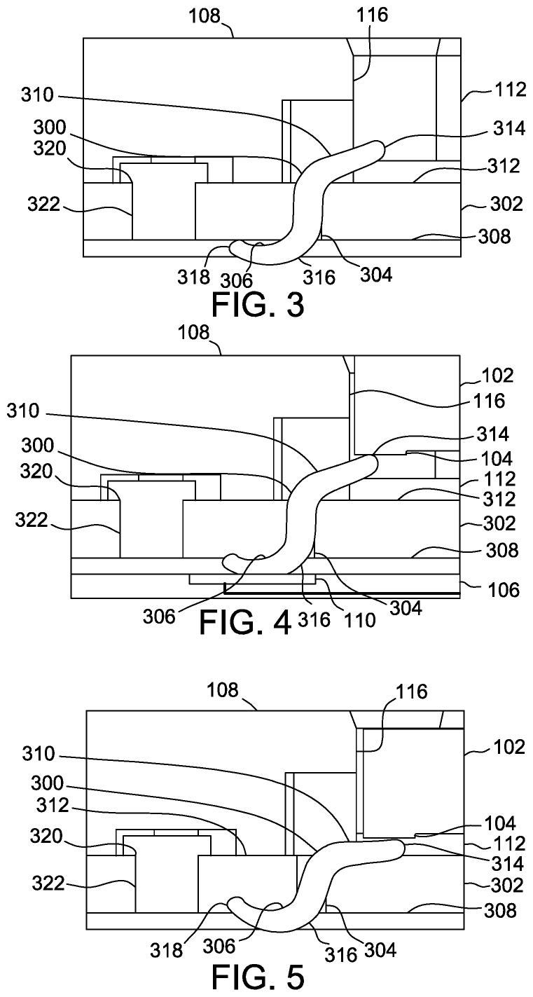

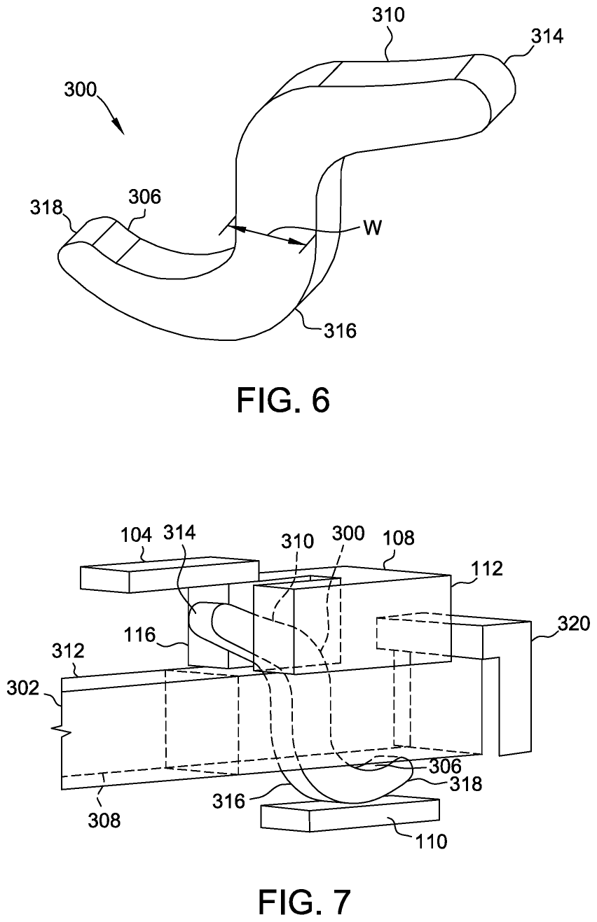

FIG. 3 is a cross-sectional diagram of one embodiment of a rotational contact 300 in test socket 108 (shown in FIG. 1) in a free state, i.e., before test socket 108 is mounted to load board 106, and before IC 102 is set. FIG. 4 is a cross-sectional diagram of rotational contact 300 in a pre-load state, i.e., test socket 108 is mounted to load board 106, but IC 102 is not yet set. FIG. 5 is a cross-sectional diagram of rotational contact 300 in a loaded state, i.e., test socket 108 is mounted to load board 106 and IC 102 is set into receptacle 114. FIG. 6 is a perspective diagram of rotational contact 300 separate from test socket 108. Rotational contact 300 is composed of an electrically conductive material, such as, for example, copper, copper alloy, aluminum, aluminum alloy, steel, or other conductive metal, or some combination thereof.

As shown in FIGS. 3-5, test socket 108 includes an elastomer retainer 302 including a slot 304. Rotational contact 300 is positioned in slot 304 and extends from receptacle 114 through slot 304 from which it protrudes and engages PCB contact 110. Rotational contact 300 includes a surface 306 resting on a bottom surface 308 of elastomer retainer 302. Rotational contact 300 further includes an arm 310 extending from a top surface 312 of elastomer retainer 302. Elastomer retainer 302 holds rotational contact 300 in place with respect to test socket 108, and provides force to maintain good connections between rotational contact 300 and contact pads 104 of IC 102, and between rotational contact 300 and PCB contact 110 of load board 106.

Arm 310 of rotational contact 300 terminates at a first end with a tip 314 that engages and translates, or scrubs, on contact pad 104 of IC 102. Rotational contact 300 terminates at a second end, opposite tip 314, with a curved portion 316 and a tail 318. Surface 306, which rests on elastomer retainer 302, is a concave inner surface of curved portion 316.

In some embodiments, tip 314 of rotational contact 300 is pointed, or “sharp,” to enable effective scrubbing on contact pad 104 of IC 102. For example, in one embodiment, tip 314 is rounded with a radius of about 0.08 millimeters. More generally, in certain embodiments, tip 314 is rounded with a radius of no more than 0.10 millimeters.

Arm 310 of rotational contact 300 is substantially straight and, in certain embodiments, is narrower at tip 314 than at the opposite end of rotational contact 300. For example, arm 310 may taper, having a narrow width, W, near tip 314, to a wider width, W, near the point of contact with PCB contact 110. The taper of arm 310 enables greater mechanical strength of rotational contact 300 due to the increased width, W. The taper of arm 310 also enables efficient current conduction by avoiding discontinuities in the surfaces of rotational contact 300. In one embodiment, for example, the width W is about 0.36 millimeters and a center of rotational contact 300.

Surface 306 of rotational contact 300 rests on elastomer retainer 302 when test socket 108 is in the free state, and moves towards elastomer retainer 302 when in the pre-load or loaded state, causing elastomer retainer 302 to deform to partially receive rotational contact 300. Surface 306 and tail 318 are rounded to provide smooth deformation of elastomer retainer 302 and reduce wear on elastomer retainer 302 when deforming. In one embodiment, for example, curved portion 316 has an outer radius of about 0.56 millimeters and an inner radius of about 0.3 millimeters, and tail 318 has a radius of about 0.05 millimeters. More generally, in certain embodiments, tail 318 has a radius of 0.05 millimeters or larger.

When test socket 108 is mounted on load board 106 (i.e., the pre-load state shown in FIG. 4), PCB contact 110 engages rotational contact 300, and load board 106 engages socket body 112. Upon engaging rotational contact 300, PCB contact 110 forces rotational contact 300 upward to compress elastomer retainer 302 against socket body 112. Elastomer retainer 302, upon engagement with load board 106 and compression of elastomer retainer 302, applies a pre-load force to rotational contact 300. The pre-load force applied to rotational contact 300 ensures good electrical contact between rotational contact 300 and PCB contact 110, and must be at least partially overcome by insertion of IC 102 into receptacle 114. The amount of pre-load force provided by elastomer retainer 302 is customizable for a given application by selecting appropriate properties of elastomer retainer 302.

When IC 102 is inserted, or set, into receptacle 114 of test socket 108, contact pad 104 engages tip 314 of rotational contact 300, forcing tip 314 downward. Downward motion of tip 314 results in rotational motion of rotational contact 300 within slot 304 of elastomer retainer 302. Tip 314 of rotational contact 300 also functions as a fulcrum, or pivot point, transferring downward force of IC 102 into a compressing force, or a contact force, applied by arm 310 onto top surface 312 elastomer retainer 302. Likewise, PCB contact 110 also operates as a pivot point to transfer downward force of IC 102 to a loading force, which may be a rotational force, to cause tail 318 to compress bottom surface 308 of elastomer retainer 302. Because motion of rotational contact 300 is rotational, tip 314 of rotational contact 300 translates, or scrubs, along contact pad 104. The scrub produced by rotational motion of rotational contact 300 and, more specifically, tip 314 reduces electrical resistance of the connection between contact pad 104 and rotational contact 300, and ultimately reducing the contact electrical resistance of the electrical connection between contact pad 104 of IC 102 and PCB contact 110 of load board 106.

When IC 102 is removed from receptacle 114 of test socket 108, elastomer retainer 302, previously deformed under the loading force, returns to the pre-load state and reverses the loading force on rotational contact 300, and returns rotational contact 300 to the pre-load state with a return force.

Socket body 112 includes an insert 320 that extends through an insert hole 322 defined in elastomer retainer 302. Inserts 320 hold elastomer retainer 302 in place with respect to socket body 112 when rotational contact 300 rotates and compresses elastomer retainer 302. Accordingly, elastomer retainer 302 generates an opposite force against rotational contact 300 to press rotational contact 300 against contact pad 104 of IC 102 for a reliable electrical connection.

FIG. 7 is a perspective diagram of rotational contact 300 (shown in FIGS. 3-6) positioned in test socket 108 in the free state. FIG. 7 illustrates contact pad 104 separate from IC 102, and illustrates PCB contact 110 separate from load board 106. Rotational contact 300 is positioned in slot 304 defined in elastomer retainer 302. FIG. 7 illustrates only the portion of socket body 112 proximate the shown rotational contact 300. Embodiments of test socket 108 may include any number of rotational contacts 300 packaged in respective slots 304 of elastomer retainer 302 along one or more dimensions. For example, one embodiment of test socket 108, shown in FIG. 2, is configured for a QFN IC having a plurality of rotational contacts 300 arranged on all four sides of socket body 112. In such an embodiment, for example, slots 304 are independently defined in elastomer retainer 302 to constrain motion of rotational contacts 300 to rotational motion in the plane shown in FIGS. 3-5. In certain embodiments, elastomer retainer 302 spans multiple rotational contacts 300 positioned in their respective slots 304. Elastomer retainer 302 provides force to maintain good, or “tight,” connections between rotational contact 300 and contact pads 104 of IC 102, and between rotational contact 300 and PCB contact 110 of load board 106.

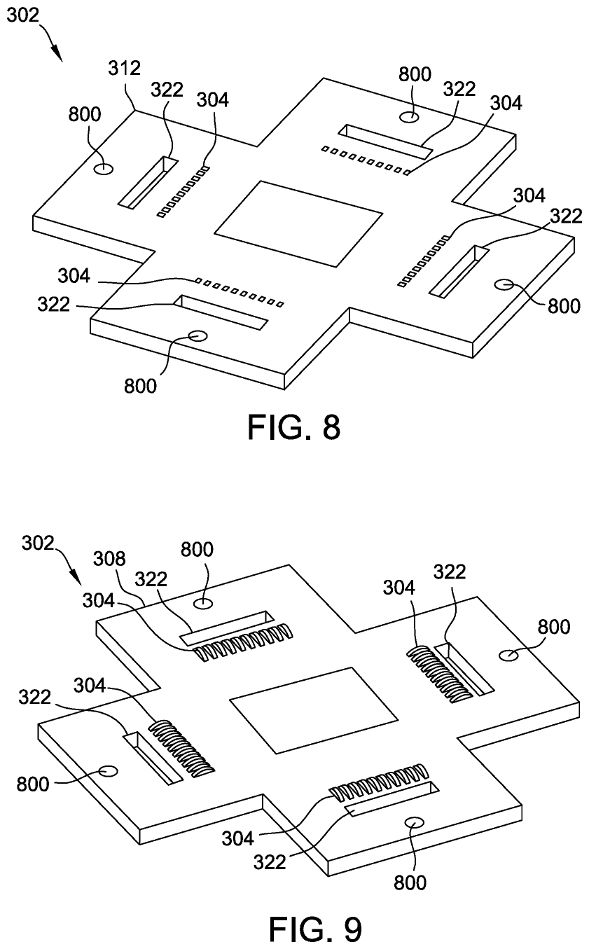

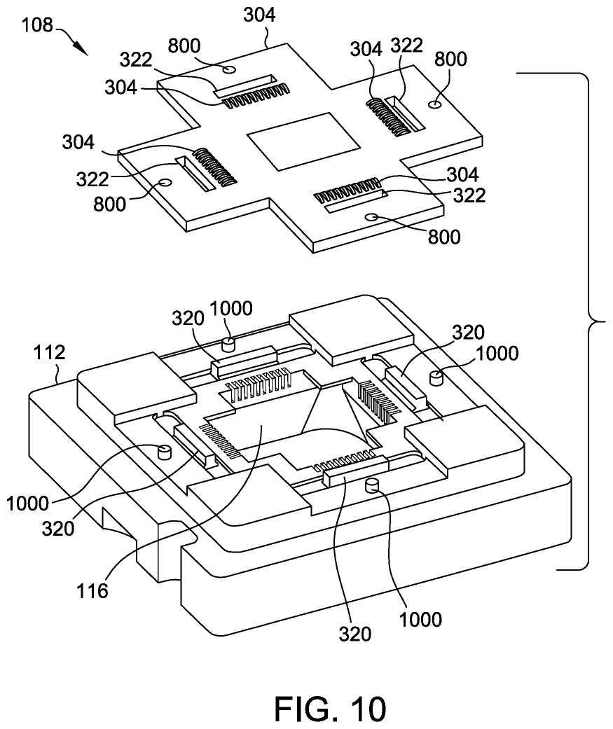

FIGS. 8 and 9 are perspective diagrams of elastomer retainer 302, and FIG. 10 is an exploded diagram of test socket 108 showing elastomer retainer 302 removed from socket body 112. As described above, elastomer retainer 302 includes slots 304 in which rotational contacts 300 may be positioned and insert holes 322 into which inserts 320 may be positioned to hold elastomer retainer 302 in position with respect to socket body 112. Elastomer retainer 302 further includes dowel pin holes 800 aligning with dowel pins 1000 of socket body 112. Dowell pins 1000 may be inserted into dowel pin holes 800 to accurately align elastomer retainer 302 with socket body 112 during assembly, so that each slot 304 and corresponding rotational contact 300 may be aligned with the corresponding contact pad 104 and PCB contact 110.

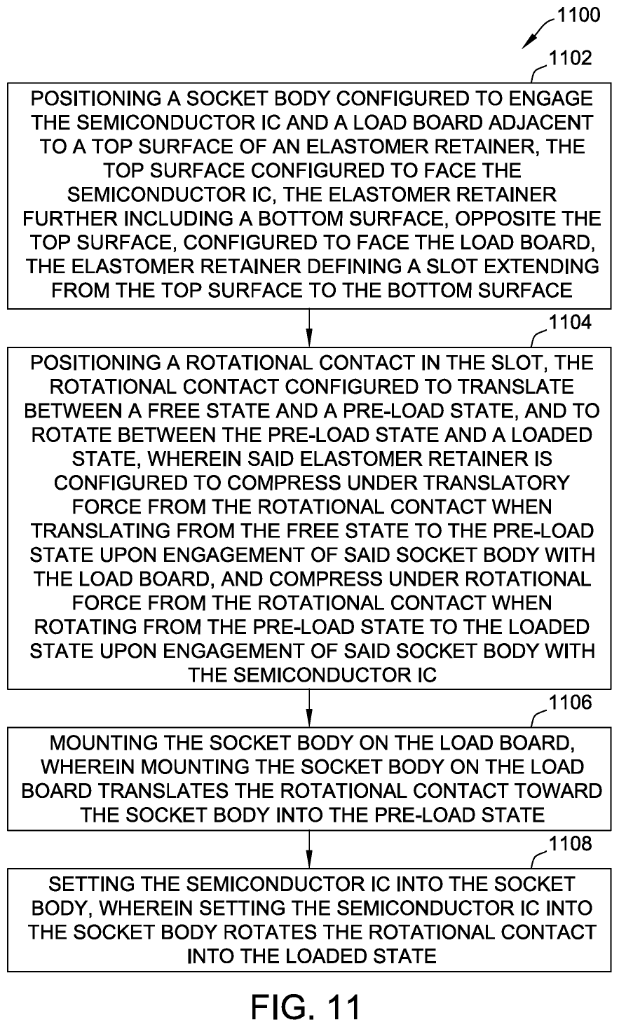

FIG. 11 is a flow diagram for a method 1100 of assembling test socket 108 shown in FIGS. 1-5 and 7. Socket body 112, which is configured to engage semiconductor IC 102 and load board 106, is positioned 1102 adjacent to top surface 312 of elastomer retainer 302. Top surface 312 is configured to face semiconductor IC 102. Elastomer retainer 302 further includes bottom surface 308, opposite top surface 312, configured to face load board 106. Elastomer retainer 302 defines slot 304 extending from top surface 312 to bottom surface 308.

Rotational contact 300 is positioned 1104 in slot 304. Rotational contact 300 is configured to move (e.g., translate or rotate) between a free state and a pre-load state, and to move between the pre-load state and a loaded state. Elastomer retainer 302 is configured to compress under a pre-load force, which may be a translatory force, from rotational contact 300 when translating from the free state to the pre-load state upon engagement of socket body 112 with load board 106, and compress under loading force from rotational contact 300 when rotating from the pre-load state to the loaded state upon engagement of socket body with semiconductor IC 102.

Socket body 112 is mounted 1106 on load board 106. Mounting socket body 112 on load board 106 moves rotational contact 300 toward socket body 112 into the pre-load state. Semiconductor IC 102 is set 1108 into socket body 112. Setting semiconductor IC 102 into socket body 112 moves rotational contact 300 into the loaded state and translates tip 314 the rotational contact 300 across contact pad 104 of semiconductor IC 102.

The technical effects of the systems and apparatuses described herein may include: (a) providing customizable pre-load force via an elastomer retainer; (b) enabling scrub across semiconductor IC contact pads when setting the IC into the test socket; (c) reducing contact electrical resistance between test socket and IC by introducing scrub when setting the IC in the test socket; and (d) reducing scrub across the PCB contact of the load board by the rotational contact.

In the foregoing specification and the claims that follow, a number of terms are referenced that have the following meanings.

As used herein, an element or step recited in the singular and preceded with the word “a” or “an” should be understood as not excluding plural elements or steps, unless such exclusion is explicitly recited. Furthermore, references to “example implementation” or “one implementation” of the present disclosure are not intended to be interpreted as excluding the existence of additional implementations that also incorporate the recited features.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here, and throughout the specification and claims, range limitations may be combined or interchanged. Such ranges are identified and include all the sub-ranges contained therein unless context or language indicates otherwise.

Disjunctive language such as the phrase “at least one of X, Y, or Z,” unless specifically stated otherwise, is generally understood within the context as used to state that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

The systems and methods described herein are not limited to the specific embodiments described herein, but rather, components of the systems and/or steps of the methods may be utilized independently and separately from other components and/or steps described herein.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to provide details on the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A test socket for a semiconductor integrated circuit (IC), comprising:
a socket body configured to engage the semiconductor IC and a load board;
an elastomer retainer including a top surface adjacent to said socket body and configured to face the semiconductor IC, and a bottom surface, opposite the top surface, configured to face a load board, the elastomer retainer defining a slot extending from the top surface to the bottom surface; and
a rotational contact positioned in the slot, the rotational contact configured to move between a free state and a pre-load state, and to move between the pre-load state and a loaded state, wherein said elastomer retainer is configured to compress under a pre-load force from the rotational contact when moving from the free state to the pre-load state upon engagement of said socket body with the load board, and compress under a loading force from the rotational contact when moving from the pre-load state to the loaded state upon engagement of said socket body with the semiconductor IC.

2. The test socket of claim 1, wherein said rotational contact comprises a tip configured to engage a contact pad of the semiconductor IC when said rotational contact moves from the pre-load state to the loaded state.

3. The test socket of claim 2, wherein said tip of said rotational contact is configured to translate across the contact pad of the semiconductor IC when said rotational contact moves from the pre-load state to the loaded state.

4. The test socket of claim 2, wherein said rotational contact further comprises a tail at an end opposite the tip, the tail configured compress said elastomer retainer when said rotational contact moves from the pre-load state to the loaded state.

5. The test socket of claim 4, wherein said tail of said rotational contact is configured to engage a printed circuit board (PCB) pad of the load board when in the pre-load state and the loaded state.

6. The test socket of claim 1, wherein said socket body defines a receptacle into which the semiconductor IC is configured to be set.

7. The test socket of claim 1, wherein said elastomer retainer is configured to compress under a force from said rotational contact against said socket body.

8. The test socket of claim 7, wherein said socket body includes an insert, and wherein said elastomer retainer defines a hole in the top surface configured to receive said insert to hold said elastomer retainer in place with respect to said socket body.

9. A test system for a semiconductor integrated circuit (IC), the test system comprising:
a load board; and
a test socket comprising:
a socket body configured to engage the semiconductor IC and a load board;
an elastomer retainer including a top surface adjacent to said socket body configured to face the semiconductor IC, and a bottom surface, opposite the top surface, configured to face said load board, the elastomer retainer defining a slot extending from the top surface to the bottom surface; and
a rotational contact positioned in the slot, the rotational contact configured to move between a free state and a pre-load state, and to move between the pre-load state and a loaded state, wherein said elastomer retainer is configured to compress under a pre-load force from the rotational contact when moving from the free state to the pre-load state upon engagement of said socket body with said load board, and compress under a loading force from the rotational contact when moving from the pre-load state to the loaded state upon engagement of said socket body with the semiconductor IC.

10. The test system of claim 9, wherein said rotational contact comprises a tip configured to engage a contact pad of the semiconductor IC when said rotational contact moves from the pre-load state to the loaded state.

11. The test system of claim 10, wherein said tip of said rotational contact is configured to translate across the contact pad of the semiconductor IC when said rotational contact moves from the pre-load state to the loaded state.

12. The test system of claim 10, wherein said rotational contact further comprises a tail at an end opposite the tip, the tail configured to compress said elastomer retainer when said rotational contact moves from the pre-load state to the loaded state.

13. The test system of claim 12, wherein said load board comprises a PCB pad, and wherein said tail of said rotational contact is configured to engage said PCB pad when in the pre-load state and the loaded state.

14. The test system of claim 9, wherein said socket body defines a receptacle into which the semiconductor IC is configured to be set.

15. The test system of claim 9, wherein said elastomer retainer is configured to compress under a force from said rotational contact against said socket body.

16. The test system of claim 15, wherein said socket body includes an insert, and wherein said elastomer retainer defines a hole in the top surface configured to receive said insert to hold said elastomer retainer in place with respect to said socket body.

17. A method for assembling a test system for a semiconductor integrated circuit (IC), said method comprising:
positioning a socket body configured to engage the semiconductor IC and a load board adjacent to a top surface of an elastomer retainer, the top surface configured to face the semiconductor IC, the elastomer retainer further including a bottom surface, opposite the top surface, configured to face the load board, the elastomer retainer defining a slot extending from the top surface to the bottom surface; and
positioning a rotational contact in the slot, the rotational contact configured to move between a free state and a pre-load state, and to move between the pre-load state and a loaded state, wherein the elastomer retainer is configured to compress under a pre-load force from the rotational contact when moving from the free state to the pre-load state upon engagement of the socket body with the load board, and compress under a loading force from the rotational contact when moving from the pre-load state to the loaded state upon engagement of the socket body with the semiconductor IC.

18. The method of claim 17, further comprising mounting the socket body on the load board, wherein mounting the socket body on the load board translates the rotational contact toward the socket body into the pre-load state.

19. The method of claim 18, further comprising setting the semiconductor IC into the socket body, wherein setting the semiconductor IC into the socket body rotates the rotational contact into the loaded state.

20. The method of claim 19, wherein setting the semiconductor IC into the socket body translates a tip of the rotational contact across a contact pad of the semiconductor IC.
